(19) United States
(12) Patent Application Publication
(10) Pub. No.: US 2025/0216346 A1
(43) Pub. Date: Jul. 3, 2025

(54) DETERMINATION OF LAYER PROPERTIES USING WIDENING OF AN ELECTRON BEAM

(71) Applicant: Applied Materials Israel Ltd., Rehovot (IL)

(72) Inventors: Ron MEIRY, Givatayim (IL); Lior YARON, Nes Ziona (IL); Itamar SHANI, Rehovot (IL); Konstantin CHIRKO, Rehovot (IL)

(21) Appl. No.: 18/402,641

(22) Filed: Jan. 2, 2024

(51) Int. Cl. G01N 23/2251; G01B 15/00

(52) U.S. Cl. CPC G01N 23/2251; G01B 15/00; G01N 2223/102; G01N 2223/304; G01N 2223/305; G01N 2223/6116

(57) ABSTRACT

There are provided systems and methods comprising obtaining an acquisition signal informative of a semiconductor specimen comprising at least a first layer located at a first depth and a second layer located at a second depth, wherein the acquisition signal has been acquired by an electron beam examination system operative to scan the specimen with an electron beam associated with a landing energy enabling generating, in at least one of the acquisition signal or in a signal derived from the acquisition signal, a first pattern informative of a lateral edge of the first layer, and a second pattern informative of a lateral edge of the second layer, wherein the second pattern differs from the first pattern, and using at least one of the acquisition signal or the signal derived from the acquisition signal, to determine properties of at least one of the first layer or the second layer.

### TECHNICAL FIELD

The presently disclosed subject matter relates, in general, to the field of examination of a specimen, and more specifically, to the determination of layer properties of a specimen, using an electron beam.

### BACKGROUND

Current demands for high density and performance associated with ultra large-scale integration of fabricated devices require submicron features, increased transistor and circuit speeds, and improved reliability. Such demands require formation of device features with high precision and uniformity, which, in turn, necessitates careful monitoring of the fabrication process, including automated examination of the devices while they are still in the form of semiconductor wafers.

Examination processes are used at various steps during semiconductor fabrication to measure dimensions of the specimens (metrology), and/or to detect and classify defects on specimens (e.g., Automatic Defect Classification (ADC), Automatic Defect Review (ADR), etc.).

### GENERAL DESCRIPTION

In accordance with certain aspects of the presently disclosed subject matter, there is provided a system comprising one or more processing circuitries configured to obtain an acquisition signal informative of a semiconductor specimen comprising at least a first layer located at a first depth in the specimen, and a second layer located at a second depth in the specimen, higher than the first depth, wherein the acquisition signal has been acquired by an electron beam examination system operative to scan the specimen with an electron beam associated with a landing energy enabling generating, in at least one of the acquisition signal or in a signal derived from the acquisition signal, a first pattern informative of a lateral edge of the first layer, and a second pattern informative of a lateral edge of the second layer, wherein the second pattern differs from the first pattern, and use at least one of the acquisition signal or the signal derived from the acquisition signal, to determine one or more properties of at least one of the first layer or the second layer.

According to some embodiments, the one or more properties include at least one of a position of the lateral edge of the first layer, a position of the lateral edge of the second layer, a width of the first layer, or a width of the second layer.

According to some embodiments, the first pattern corresponds to a first peak informative of the lateral edge of the first layer, and the second pattern corresponds to a second peak informative of the lateral edge of the second layer, wherein the first peak and the second peak are differentiable by their width.

According to some embodiments, the first pattern corresponds to a first slope informative of the lateral edge of the first layer, and the second pattern corresponds to a second slope informative of the lateral edge of the second layer, wherein the first slope differs from the second slope.

According to some embodiments, the system is configured to use a relationship between data informative of a shape of the first pattern and of the second pattern and a depth within the specimen, to differentiate between the first pattern informative of the lateral edge of the first layer located at the first depth in the specimen and the second pattern informative of the second layer located at the second depth in the specimen, higher than the first depth.

According to some embodiments, the system is configured to use a difference between data informative of a width of the first pattern and data informative of a width of the second pattern to identify the first pattern informative of the lateral edge of the first layer and the second pattern informative of the lateral edge of the second layer.

According to some embodiments, the system is configured to use a difference between data informative of an amplitude of the first pattern and data informative of an amplitude of the second pattern to identify the first pattern informative of the lateral edge of the first layer and the second pattern informative of the lateral edge of the second layer.

According to some embodiments, the system is configured to use a difference between data informative of a slope of the first pattern and data informative of a slope of the second pattern to identify the first pattern informative of the lateral edge of the first layer and the second pattern informative of the lateral edge of the second layer.

According to some embodiments, the second layer is located deeper in the specimen than the first layer, wherein the system is configured to identify that a pattern of the signal corresponds to the first pattern informative of the lateral edge of the first layer and that another pattern of the signal corresponds to the second pattern informative of the lateral edge of the second layer based on a determination that that data informative of a width of said another pattern is larger than data informative of a width of said pattern.

According to some embodiments, the second layer is located deeper in the specimen than the first layer, wherein the system is configured to identify that a pattern of the signal corresponds to the first pattern informative of the lateral edge of the first layer, and that another pattern of the signal corresponds to the second pattern informative of the lateral edge of the second layer, based on a determination that that data informative of an amplitude of said another pattern is larger than data informative of an amplitude of said pattern.

According to some embodiments, the second layer is separated by the first layer by a layer which has a density which is smaller than a density of the first layer and than a density of the second layer.

According to some embodiments, the landing energy has been selected using one or more simulations.

According to some embodiments, the one or more simulations include determining data informative of variations of a simulated acquisition signal of the specimen for different landing energies of the simulated acquisition signal, and selecting a given landing energy for which a given simulated acquisition signal associated with this given landing energy, or a given signal derived from this given simulated acquisition signal, includes a first pattern informative of the lateral edge of the first layer and a second pattern informative of the lateral edge of the second layer, wherein the first pattern differs from the second pattern according to a criterion.

According to some embodiments, the system is configured to obtain a first acquisition signal informative of the specimen, wherein the first acquisition signal has been acquired by the electron beam examination system operative to scan the specimen with an electron beam associated with a first landing energy, determine first data informative of variations of the first acquisition signal, obtain a second acquisition signal informative of the specimen, wherein the second acquisition signal has been acquired by the electron beam examination system operative to scan the specimen with an electron beam associated with a second landing energy, higher than the first landing energy, determine second data informative of variations of the second acquisition signal, and use the first data and the second data to determine at least one of a position of the lateral edge of the first layer or a position of the lateral edge of the second layer.

According to some embodiments, the specimen includes N vertically stacked layers L₁ to L_{N}, with N≥2, wherein each layer has a different width, wherein the system is configured to obtain a plurality of different acquisition signals acquired at different landing energies, determine, for each given acquisition signal data, a derivative signal informative of variations of the given acquisition signal, thereby obtaining a set of derivative signals, use the set of derivative signals to determine one or more properties of one or more of the layers L₁ to L_{N}.

According to some embodiments, the system is configured to compare a first derivative signal obtained at a first landing energy and a second derivative signal obtained at a second landing energy, higher than the first landing energy, and determine a position of one or more lateral edges of one or more of the layers L₁ to L_{N} based on a comparison between one or more patterns that appear in the second derivative signal and one or more patterns that appear in the first derivative signal.

According to some embodiments, the system is configured to obtain a first expected amplitude for the first pattern and identifying the first pattern based on this first expected amplitude.

According to some embodiments, the system is configured to obtain a second expected amplitude for the second pattern and identifying the second pattern based on this second expected amplitude.

According to some embodiments, the specimen includes N vertically stacked layers L₁ to L_{N}, with N≥2, wherein each layer has a different width, wherein the system is configured to obtain an acquisition signal informative of the specimen, wherein the acquisition signal has been acquired by an electron beam examination system operative to scan the specimen with an electron beam associated with a width which expands from a depth of a layer Lᵢ to a depth of the next layer Lᵢ₊₁, with i from 1 to N−1, determine data informative of variations of the acquisition signal, and use the data to determine one or more properties of at least one of the layers L₁ to L_{N}.

In accordance with other aspects of the presently disclosed subject matter, there is provided a system comprising one or more processing circuitries configured to obtain at least one acquisition signal informative of a semiconductor specimen comprising at least a first layer located at a first depth in the specimen, and a second layer located at a second depth in the specimen, higher than the first depth, wherein the at least one acquisition signal has been acquired by an electron beam examination tool operative to scan the specimen with an electron beam associated, in at least part of the scan of the specimen, with a width which is larger at the second depth than at the first depth, and use at least one of the acquisition signal, or a signal derived from the acquisition signal, to determine one or more properties of at least one of the first layer or the second layer.

According to some embodiments, the system is configured to obtain a first expected amplitude for the first pattern and identifying the first pattern based on this first expected amplitude.

According to some embodiments, the system is configured to obtain a second expected amplitude for the second pattern and identifying the second pattern based on this second expected amplitude.

According to some embodiments, the specimen includes N vertically stacked layers L₁ to L_{N}, with N≥2, wherein each layer has a different width, wherein the system is configured to obtain an acquisition signal informative of the specimen, wherein the acquisition signal has been acquired by an electron beam examination system operative to scan the specimen with an electron beam associated with a width which expands from a depth of a layer Lᵢ to a depth of the next layer Lᵢ₊₁, with i from 1 to N−1, determine data informative of variations of the acquisition signal, and use the data to determine one or more properties of at least one of the layers L₁ to L_{N}.

According to some embodiments, the system can include one or more of the features described above.

In accordance with other aspects of the presently disclosed subject matter, there is provided a system comprising one or more processing circuitries configured to obtain at least one acquisition signal informative of a semiconductor specimen comprising at least a first layer located at a first depth in the specimen, and a second layer located at a second depth in the specimen, higher than the first depth, wherein the at least one acquisition signal has been acquired by an electron beam examination tool operative to scan the specimen with an electron beam associated, in at least part of the scan of the specimen, with a width which is larger at the second depth than at the first depth, and use at least one of the acquisition signal, or a signal derived from the acquisition signal, to determine one or more properties of at least one of the first layer or the second layer.

According to some embodiments, the electron beam enables generating, in the acquisition signal, or the signal derived from the acquisition signal, a first pattern informative of a lateral edge of the first layer, and a second pattern informative of a lateral edge of the second layer, wherein at least one of (i), (ii) or (iii) is met: (i) data informative of a width of the second pattern is larger than data informative of a width of the first pattern, (ii) data informative of an amplitude of the first pattern is larger than data informative of an amplitude of the second pattern, or (iii) data informative of a slope of the first pattern differs from data informative of a slope of the second pattern.

According to some embodiments, the system is configured to perform a determination of at least one of a position of the lateral edge of the first layer or a position of the lateral edge of the second layer, said determination comprising identifying at least one of the first pattern or the second pattern based on at least one of (i) data informative of a width of the first pattern and of the second pattern, (ii) data informative of an amplitude of the first pattern and of the second pattern, or (iii) data informative of a slope of the first pattern and data informative of a slope of the second pattern.

According to some embodiments, the system can include one or more of the features described above.

In accordance with other aspects of the presently disclosed subject matter, there is provided a non-transitory computer readable medium comprising instructions that, when executed by one or more processing circuitries, cause the one or more processing circuitries to perform: obtaining a plurality of different acquisition signals of a semiconductor specimen including N vertically stacked layers L₁ to L_{N}, with N≥2, wherein each layer has a different width, acquired at different landing energies, and using the plurality of different acquisition signals to determine one or more properties of one or more of the layers L₁ to L_{N}.

According to some embodiments, the non-transitory computer readable medium comprises instructions that, when executed by the one or more processing circuitries, cause the one or more processing circuitries to identify patterns in the different acquisition signals to determine edge position of each of the layers L₁ to L_{N}.

In accordance with other aspects of the presently disclosed subject matter, there is provided a non-transitory computer readable medium comprising instructions that, when executed by one or more processing circuitries, cause the one or more processing circuitries to perform one or more of the methods described hereinafter.

According to some examples, the proposed solution enables accurate determination of one or more properties of buried layers, such as dimensions, edge position, etc.

According to some examples, the proposed solution enables differentiating between buried layers of a specimen.

According to some examples, the proposed solution enables determining critical dimensions of layers located at multiple depths within a specimen, even in complex multi-material layered patterns.

According to some examples, the proposed solution enables analyzing properties of a plurality of vertically stacked layers.

According to some examples, the proposed solution enables determining whether the layers of a manufactured specimen comply with the design data.

According to some examples, the proposed solution proposes using landing energies which provide a smaller resolution than other solutions, but which enable differentiating between lateral edges of layers located at different depths within the specimen.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIGS. 2A to 2E illustrate various non-limitative examples of specimens including a plurality of layers located at different depths. Various methods are proposed hereinafter to determine one or more properties of one or more of these layers.

FIG. 3 illustrates a generalized flow-chart of a method of determining one or more properties of different layers located at different depths within a specimen.

FIG. 4A illustrates a non-limitative example of an acquisition signal of a specimen, which can be used in the method of FIG. 3.

FIG. 4B illustrates a non-limitative example of derivative signal of the acquisition signal of FIG. 4A, which includes two patterns informative of lateral edges of two different layers of a specimen.

FIG. 5A illustrates a generalized flow-chart of a method of differentiating between patterns informative of layers located at different depths, based on the width of the patterns.

FIG. 5B illustrates an example in which the top layer has a smaller width than the bottom layer.

FIG. 5C illustrates an example of derivative signal which can be obtained based on the acquisition signal of the specimen of FIG. 5B.

FIG. 5D illustrates a generalized flow-chart of a method of differentiating between patterns informative of layers located at different depths, based on the amplitude of the patterns.

FIG. 5E illustrates a generalized flow-chart of a method of differentiating between patterns informative of layers located at different depths, based on the expected amplitude of the patterns.

FIGS. 6A and 6B illustrate non-limitative examples of different shapes of an electron beam which can be used to determine one or more properties of one or more buried layers.

FIG. 7 illustrates a generalized flow-chart of a method of determining one or more properties of different layers located at different depths within a specimen.

FIG. 8 illustrates a generalized flow-chart of a method of determining one or more landing energies of an electron beam enabling determining one or more properties of one or more buried layers.

FIG. 9A illustrates a non-limitative example of a specimen for which the method of FIG. 8 can be used.

FIG. 9B illustrates a non-limitative example of derivative signals of (simulated or real) acquisition signals which can be obtained for the specimen of FIG. 9A, by using the method of FIG. 8.

FIG. 10 illustrates a generalized flow-chart of a method of using acquisition signals acquired at different landing energies to determine positions of lateral edges of different buried layers.

FIG. 11 illustrates a generalized flow-chart of a method enabling determining the landing energies used in the method of FIG. 10.

### DETAILED DESCRIPTION OF EMBODIMENTS

According to some examples, a semiconductor specimen can include a plurality of layers, which are vertically stacked. The layers are therefore located at different heights (different depths) within the specimen. It is intended to determine one or more properties of the layers, such as, but not limited to, position of the lateral edge of one or more of the layers, width of one or more of the layers, etc. Various systems and methods are described hereinafter, which enable determining one or more properties of buried layers in a specimen, based on one or more acquisition signals acquired by an electron beam examination system.

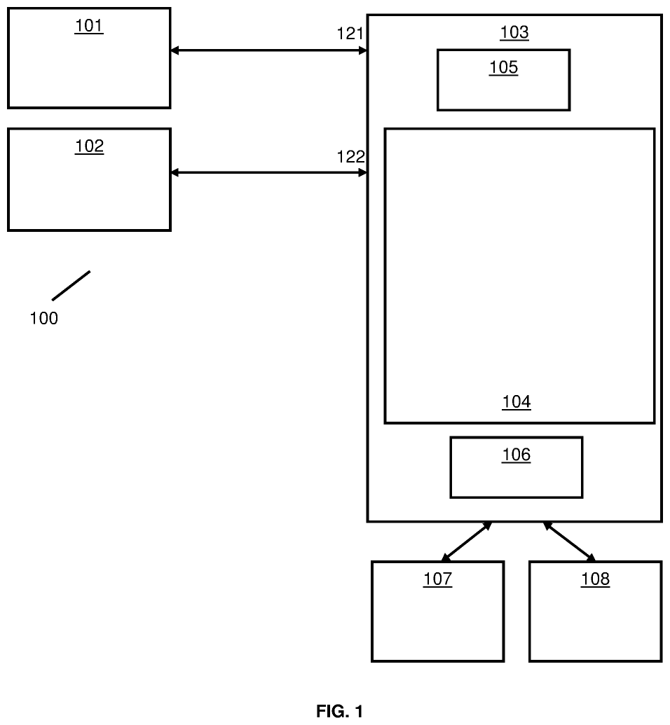

Bearing this in mind, attention is drawn to FIG. 1 illustrating a functional block diagram of an examination system 100 in accordance with certain examples of the presently disclosed subject matter.

It is noted that the teachings of the presently disclosed subject matter are not bound by the examination system 100 described with reference to FIG. 1. Equivalent and/or modified functionality can be consolidated or divided in another manner, and can be implemented in any appropriate combination of software with firmware and/or hardware and executed on a suitable device. The examination system 100 can be a standalone network entity, or integrated, fully or partly, with other network entities. Those skilled in the art will also readily appreciate that the data repositories can be consolidated or divided in other manner; databases can be shared with other systems or be provided by other systems, including third party equipment. The examination system illustrated in FIG. 1 can be implemented in a distributed computing environment, in which the aforementioned functional modules shown in FIG. 1 can be distributed over several local and/or remote devices, and can be linked through a communication network.

The examination system 100 illustrated in FIG. 1 can be used for examination of a specimen (e.g., of a wafer and/or parts thereof) as part of the specimen fabrication process. The illustrated examination system 100 comprises computer-based system 103 operatively connected to one or more low-resolution examination tools 101 and/or one or more high-resolution examination tools 102 and/or other examination tools. The examination tools are configured to capture images and/or to review the captured image(s) and/or to enable or provide measurements related to the captured image(s).

System 103 includes at least one processing circuitry 104 operatively connected to a hardware-based input interface 105 and to a hardware-based output interface 106. System 103 can be implemented as stand-alone computer(s) to be used in conjunction with the examination tools. Alternatively, the respective functions of the system can, at least partly, be integrated with one or more examination tools.

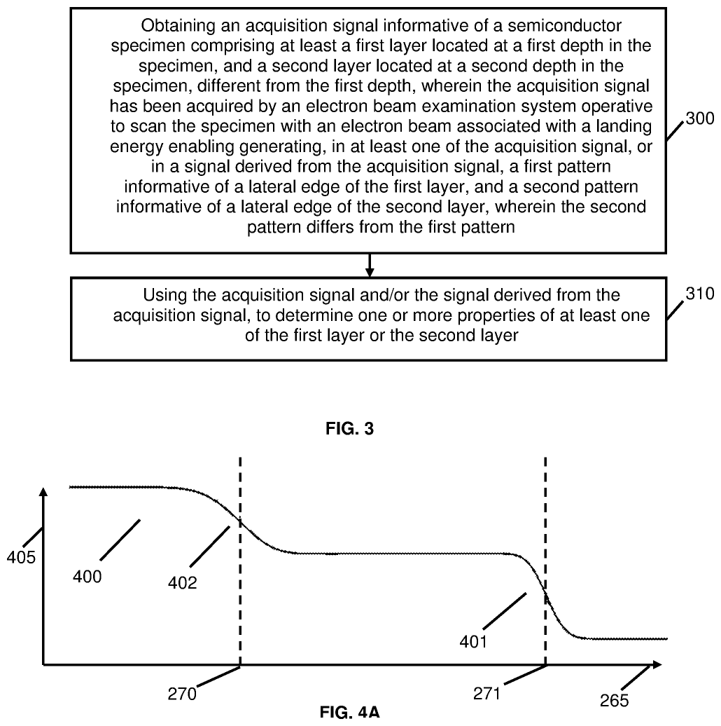

The processing circuitry 104 is configured to provide processing necessary for performing various operations, as further detailed with reference to FIGS. 3, 5A, 5B, 5C, 7C, 8, 10 and 11.

System 103 is configured to receive, via input interface 105, input data. Input data can include data (and/or derivatives thereof and/or metadata associated therewith) produced by one or more examination tools 101, 102, and/or provided by another computerized system. It is noted that input data can include acquisition signals (resulting from the acquisition of a specimen), simulated acquisition signals (resulting from the simulation of the acquisition of a specimen), synthetic acquisition signals, images (e.g., captured images, images derived from the captured images, simulated images, synthetic images, etc.) and associated numeric data (e.g., metadata, hand-crafted attributes, etc.). It is further noted that image data can include data related to a layer of interest and/or to one or more other layers of the specimen.

System 103 is further configured to process at least part of the received input data and send the results (or part thereof), via the output interface 106, to a storage system 107, and/or to examination tool(s), and/or to a computer-based graphical user interface (GUI) 108 for rendering the results and/or to external systems. This is however not limitative.

By way of non-limiting example, a specimen can be examined by one or more low-resolution examination tools 101 (e.g., an optical inspection system, low-resolution SEM, etc.). The resulting data (image data 121) informative of low-resolution images of the specimen can be transmitted—directly or via one or more intermediate systems—to system 103. Alternatively, or additionally, the specimen can be examined by a high-resolution machine 102 (e.g., a subset of potential defect locations selected for review can be reviewed by a scanning electron microscope (SEM) or Atomic Force Microscopy (AFM)). The resulting data (high-resolution image data 122) informative of high-resolution images of the specimen can be transmitted—directly or via one or more intermediate systems—to system 103. In some cases, the same examination tool can provide low-resolution image data and high-resolution image data.

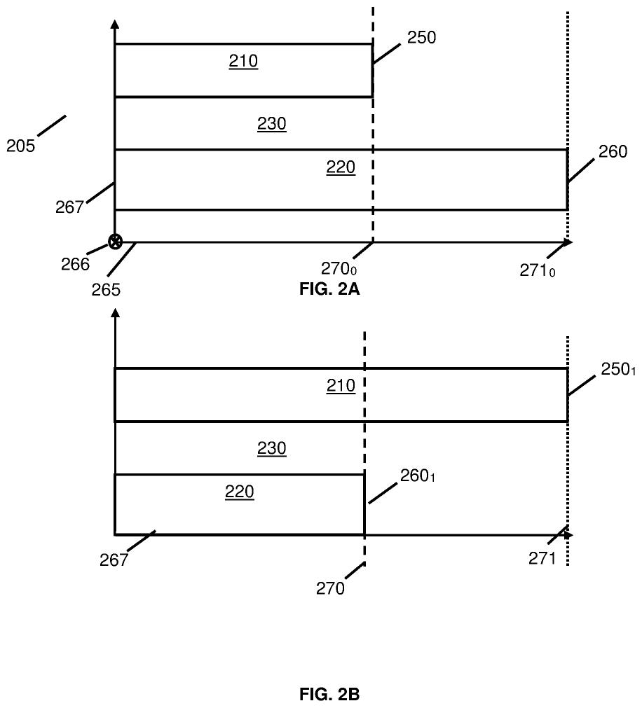

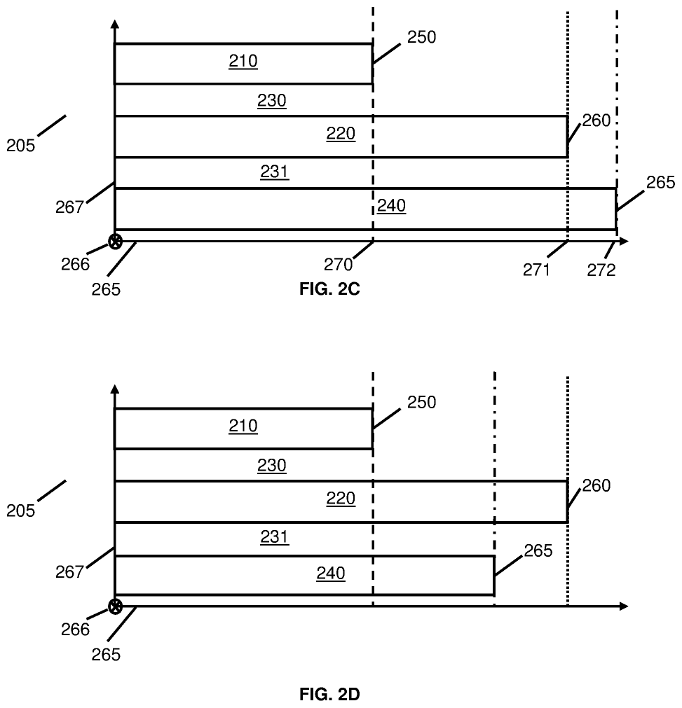

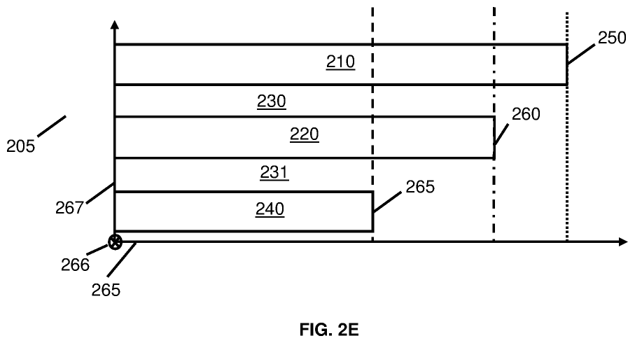

Attention is now drawn to FIG. 2A, which depicts a specimen 205 including a plurality of buried layers. In particular, the layers are vertically stacked, and each layer is associated with a different width. In this non-limitative example, two buried layers (first layer 210 and second layer 220) are depicted. The second layer 220 is located at a depth which is higher than the depth of the first layer 210 within the specimen. This is however not limitative, and the specimen can include more than two layers. Note that the shape of the layers can be also different than the layers as depicted in FIG. 2A.

In some examples, the first layer 210 and the second layer 220 are separated by a layer 230 made of material which is different from the material of the first layer 210 and of the second layer 220. In particular, the layer 230 can have a density which is smaller than the density of the first layer 210 and the density of the second layer 220. For example, the first layer 210 and the second layer 220 are made of SiGe and are separated by a layer 230 made of Si. This example is not limitative. Note that the first layer 210 and the second layer 220 can have the same composition and/or the same density, or can have different compositions and/or different densities.

In some examples, the method(s) described hereinafter enable determining various properties of the first layer 210 and/or of the second layer 220 (and/or of additional layers, if they are present). For example, the method(s) can enable determining the location of the lateral edge of each layer, which corresponds to the end of the layer. This lateral edge generally separates the layer from vacuum or from a different layer. FIG. 2A depicts lateral edge 250 of the first layer 210 and lateral edge 260 of the second layer 220. The location of the lateral edge of a layer provides information on the dimension(s) of the layer. It is possible to define three orthogonal axes: two axes in the plane of the specimen (horizontal X axis 265 and vertical Y axis 266 in the plane of the specimen—which correspond respectively to the horizontal X axis and vertical Y axis of an image of the specimen acquired from the top) and a height Z axis (depth axis) 267. This definition is not limitative and is a matter of convention. The position of the lateral edge 250 along the horizontal axis X is noted 270₀ and the position of the lateral edge 260 along the horizontal X axis is noted 271₀.

When the specimen is manufactured, defects in the manufacturing process or other defects can induce a deviation between the actual specimen and the design data. In some examples, the position of the lateral edge of one or more layers may differ from the required position. In some examples, the design data may dictate for example that the first layer 210 (top layer) ends before the second layer 220 (bottom layer), as illustrated in FIG. 2A. In other words, the width (in a side-sectional view) of the first layer 210 should be smaller than the width (in a side-sectional view) of the second layer 220. However, upon manufacturing, it can occur that the width of the first layer 210 is actually larger than the width of the second layer 220. This actual configuration is illustrated in FIG. 2B.

The position of the lateral edge 260₁ along the horizontal axis X is noted 270 and the position of the lateral edge 260 along the horizontal X axis is noted 271.

In some examples, the method(s) described hereinafter can enable determining the position of the lateral edges of one or more of the layers present in the specimen. In addition, the method(s) described hereinafter can enable determining to which layer each lateral edge belongs. For example, the method(s) can be used to identify that the lateral edge 250₁ is the lateral edge of the top layer (first layer 210) and that the lateral edge 260₂ is the lateral edge of the bottom layer (second layer 220). This is also applicable to more than two layers.

In some examples, the method(s) described hereinafter can enable determining which layer among the first layer 210 and the second layer 220 is buried at a deeper level than the other (and, conversely, which layer among the first layer 210 and the second layer 220 is the closest to the surface of the specimen). This is also applicable to more than two layers.

Note that the scale of the drawings is not necessarily realistic and has been selected to facilitate understanding of the drawings. One or more of the method(s) described hereinafter can be used to determine modifications with respect to the design data, such as the modification illustrated in FIG. 2B, or other modifications.

FIG. 2C illustrates a non-limitative example in which an additional third layer 240 is present, located below the second layer 220. Each of the layers have a different width—therefore the respective lateral edge of each layer has a different position. The third layer 240 is located at the higher depth, then the second layer 220 and the first layer 210. The position of the lateral edge 265 of the third layer 240 is noted 272. The third layer 240 is separated from the second layer 220 by a layer 231. The density of the layer 231 can be smaller than the respective density of the first, second, and third layers 210, 220, and 240. In some examples, the density of the layer 231 is the same as the density of the layer 230. This is not limitative. In some examples, the material of each of the layers 210, 220, and 240 is the same. This is not limitative. In some examples, the method(s) described hereinafter can be used to identify that the lateral edge 250 is the lateral edge of the top layer (first layer 210), that the lateral edge 260 is the lateral edge of the middle layer (second layer 220), and that the lateral edge 265 is the lateral edge of the bottom layer (third layer 240).

Although FIGS. 2A and 2C describe a configuration in which the deeper the layer, the wider the layer, this is not limitative. The method described hereinafter can be used for a specimen with a different distribution of the width between the layers. For example, in FIG. 2D, the widest layer is the middle layer 220, then the bottom layer 240 and the top layer 210. In FIG. 2E, the widest layer is the top layer 210, then the middle layer 220 and the bottom layer 240. These examples are not limitative and a different number of layers and/or a different distribution of the widths between the layers can be used.

Attention is now drawn to FIG. 3.

The method of FIG. 3 includes obtaining (operation 300) an acquisition signal informative of a semiconductor specimen comprising (at least) a first layer and a second layer. The specimen can include more than two layers. The first layer and the second layer are located at different heights (different depths) in the specimen and have different widths. Non-limitative examples of specimens have been described with reference to FIGS. 2A to 2E. Assume for example that the second layer is located deeper in the specimen than the first layer, as in FIG. 2B, in which the second layer 220 is located deeper in the specimen than the first layer 210.

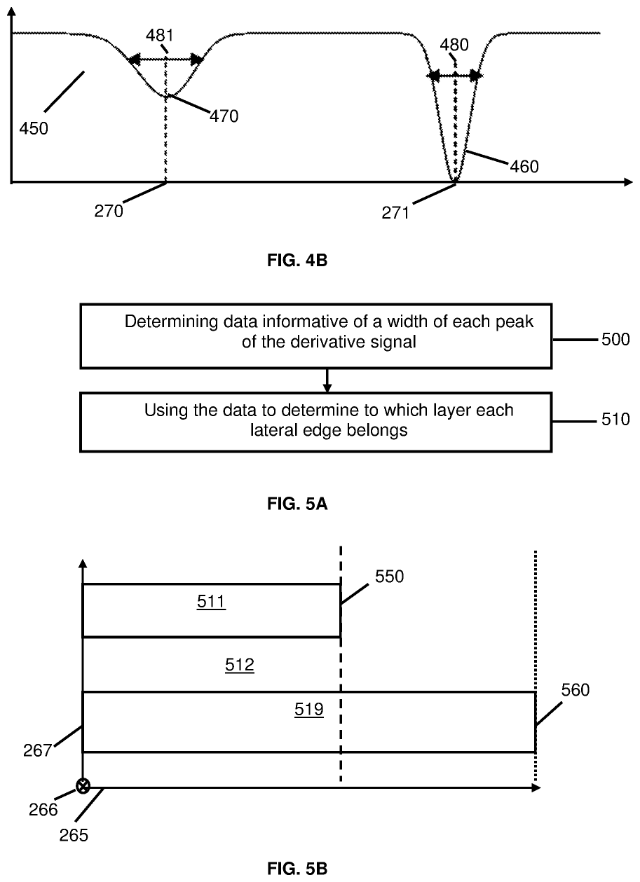

The acquisition signal has been acquired by an electron beam examination system operative to scan the specimen with an electron beam associated with a landing energy. This landing energy enables generating, in the acquisition signal and/or in a signal derived from the acquisition signal, a first pattern informative of a lateral edge of the first layer, and a second pattern informative of a lateral edge of the second layer. The signal derived from the acquisition signal can correspond to a signal informative of variations of the acquisition signal (e.g., derivative of the acquisition signal). The second pattern differs from the first pattern. The first pattern and the second pattern are located at different positions along the horizontal axis. In addition, data informative of a shape of the first pattern can differ from data informative of a shape of the second pattern. The first and second patterns can correspond for example to steep slopes in the acquisition signals (see for example reference 401 and reference 402 in FIG. 4A), or to peaks in a signal informative of variations of the acquisition signal (see for example reference 460 and reference 470 in FIG. 4B). Peaks correspond to local extremum in the derivative of the acquisition signal (such as local minima).

In case the first and second patterns are identified in the acquisition signal, the slope of the first pattern can differ from the slope of the second pattern. In particular, in the scenario of FIG. 2B, since the second layer is located deeper in the specimen than the first layer, and the edge of the second layer is underneath the first layer, the slope of the second pattern (see slope 402) is smaller than the slope of the first pattern (see slope 401).

In case the first and second patterns are identified in the derivative of the acquisition signal, data informative of a width of the first pattern can differ from data informative of a width of the second pattern. In particular, in the scenario of FIG. 2B, since the second layer is located deeper in the specimen than the first layer, and the edge of the second layer is underneath the first layer, data informative of a width of the second pattern is larger than data informative of a width of the first pattern. This enables differentiating between the lateral edge of the first layer (top layer) and the lateral edge of the second layer (bottom layer). This can be generalized to more than two layers, as explained hereinafter.

In case the first and second patterns are identified in the derivative of the acquisition signal, data informative of an amplitude of the first pattern can differ from data informative of an amplitude of the second pattern. In particular, as explained hereinafter, in at least some configurations of specimens, since the second layer is located deeper in the specimen than the first layer, data informative of an amplitude of the first pattern is larger than data informative of an amplitude of the second pattern. This enables differentiating between the lateral edge of the first layer (top layer) and the lateral edge of the second layer (bottom layer). This can be generalized to more than two layers, as explained hereinafter.

The method further includes (operation 310) using the acquisition signal and/or the signal derived from the acquisition signal (such as a signal informative of variations of the acquisition signal) to determine one or more properties of at least one of the first layer or the second layer. The derivative signal can correspond to the derivative of the acquisition signal along the horizontal X axis. In some cases, the acquisition signal is a 2D signal: a first derivative signal of the acquisition signal is determined along a first direction (X axis) and a second derivative signal of the acquisition signal is determined along a second direction (Y axis).

The acquisition signal obtained at operation 300 corresponds, e.g., to a pixel intensity signal (grey level signal) provided by the electron beam examination tool (such as a SEM). In some examples, the acquisition signal can correspond to a 1D signal, corresponding to the measured pixel intensity along a direction of the specimen (e.g., horizontal X direction in the plane of the specimen). A non-limitative example of acquisition signal 400 is illustrated in FIG. 4A. Assume that the acquisition signal 400 has been acquired by an electron beam examination tool from a specimen comprising the layers depicted in FIG. 2A. The acquisition signal 400 is expressed as a pixel intensity 405 with respect to position along the horizontal X axis 265. As visible in FIG. 4A, at the position of each lateral edge, the acquisition signal 400 undergoes a large variation. In particular, there is a steep slope in the acquisition signal. At position 271 which corresponds to the position of the lateral edge 260₁, a first slope 401 is present and at position 270 which corresponds to the lateral position of the edge 260₂, a second slope 402 is present.

FIG. 4B illustrates a derivative signal 450 which is the derivative (along the horizontal X axis) of the acquisition signal 400 of FIG. 4A obtained for the specimen depicted in FIG. 2A. As visible in FIG. 4B, the derivative signal 450 includes two main peaks: a first peak 460 is located at the position of the lateral edge 250₁ of the first layer 210 and a second peak 570 is located at the position of the lateral edge 260 of the second layer 220. Note that in this example, each peak corresponds to a local minimum. This is however not limitative.

In some examples, operation 310 can include determining the width of each peak. In the example of FIG. 4B, a first width 480 of the first peak 460 is determined, and a second width 481 of the second peak 470 is determined. Note that this is not limitative, and other properties of each peak can be determined, such as the amplitude of each peak, or the area of each peak, or other relevant data characterizing each peak.

In some examples, the one or more properties include at least one of a position of a lateral edge of the first layer or a position of a lateral edge of the second layer. Positions of the lateral edges can be determined using various methods. In some examples, they can be identified in the acquisition signal itself, by identifying areas of the acquisition signal in which steep slopes are present. In other examples, this can be determined by identifying the main peaks in the derivative signal. The first peak corresponds to a lateral edge of one of the layers, and the second peak corresponds to a lateral edge of another layer. Note that this is applicable to more than two layers: each peak corresponds to a lateral edge of a different layer.

The method enables not only determining the position of the lateral edge of each layer, but also enables determining to which layer each lateral edge belongs. The mere identification of the peaks in the derivative signal provides the location of the edge of each layer. However, the location of the peaks does not necessarily indicate to which layer each edge belongs. This is due to the fact that manufacturing errors can cause that the actual specimen differs from the design data. In particular, it can occur that although the second layer was supposed to be wider than the first layer, the actual specimen includes a first layer which is wider than the second layer. It is therefore unknown in advance which layer is wider. According to some examples, the method proposes to use a relationship between data informative of the shape of the first pattern and of the second pattern and a depth within the specimen to differentiate between the first pattern informative of the lateral edge of the first layer located at the first depth in the specimen and the second pattern informative of the second layer located at the second depth in the specimen, higher than the first depth.

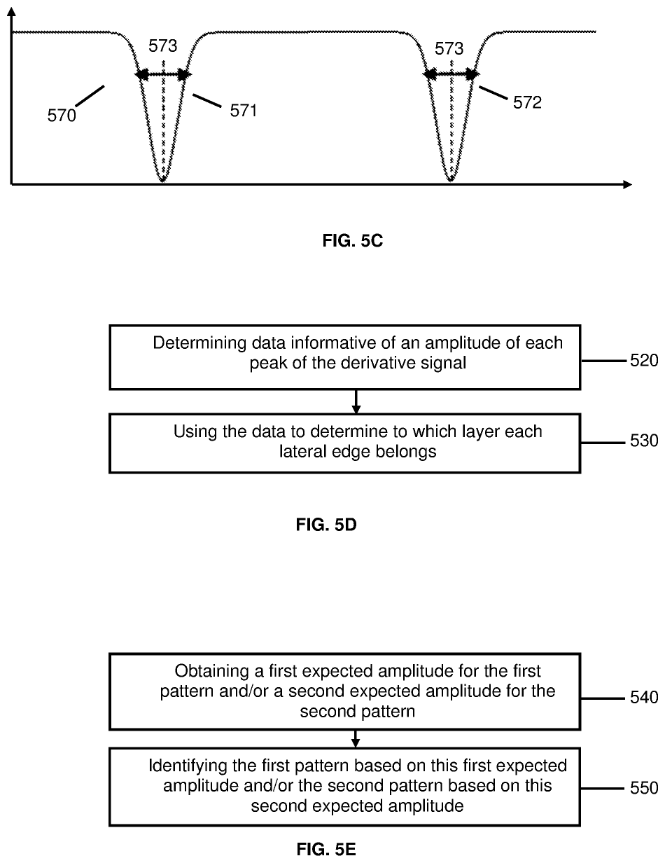

In the method of FIG. 5A, the method uses a relationship between a width of the patterns in the derivative signal and the depth in the specimen to differentiate between the peaks informative of edges of different layers. In order to determine to which layer each lateral edge belongs, operation 310 can include (see FIG. 5A) determining (operation 500) data informative of the width of each peak (corresponding to a local extremum, such as a local minima), and using (operation 510) this data to determine to which layer each lateral edge belongs. Operation 510 can rely on the following principles. Assume that the second layer is located at a deeper location (along the height axis Z of the specimen) than the first layer, and that the second layer is covered by the first layer, as illustrated in FIG. 2A. It is expected that the width (and/or the standard deviation) of the peak of the derivative signal corresponding to the lateral edge of the bottom layer (second layer 220 in FIG. 2A) will be larger than the width (and/or the standard deviation) of the peak of the derivative signal corresponding to the lateral edge of the first layer (which is the top layer, and is located closer to the surface of the specimen than the second layer). This is due to the fact that, for certain values of the landing energy of the electron beam, the width of the peak informative of a lateral edge of a layer is higher for a bottom layer than for a top layer (since the beam has encountered more material along the height direction and therefore its width has expanded).

The difference in the width between the peaks can be used to indicate whether the peak corresponds to the lateral edge of the upper layer (smaller standard deviation relative to the other peak) or to the lateral edge of the bottom layer (higher standard deviation relative to the other peak). In the example of FIG. 4B, since the second peak 470 has a width 481 which is larger than the width 480 of the first peak 460, this indicates that the second peak corresponds to the lateral edge of the bottom layer, and that the first peak corresponds of the lateral edge of the top layer. The position of the second peak in the derivative signal corresponds to the position of the lateral edge (along the horizontal axis X) of the bottom layer and the position of the first peak in the derivative signal indicates the position of the lateral edge of the top layer (along the horizontal axis X). The position of each lateral edge of each layer can be used to determine the width of each layer.

Note that if the specimen is manufactured as described in FIG. 5B, in which the top layer 511 (with lateral edge 550) has a smaller width than the bottom layer 519 (with lateral edge 560—the bottom layer 519 being separated by the top layer by a layer 512 with a smaller density than the layers 511, 519, or by vacuum), it can occur that the two patterns (informative of the respective edges 550, 560 of the top and bottom layers), are located at a different position along the horizontal axis 265, but have similar shapes. This is due to the fact that the edge of the bottom layer is not covered by a layer with high density. This is visible in FIG. 5C, in which the derivative 570 of the acquisition signal includes a first pattern 571 informative of the lateral edge 550 of the top layer and a second pattern 572 informative of the lateral edge 560 of the bottom layer. Since the two patterns have the same width 573, it can be understood that the configuration of the specimen is as illustrated in FIG. 5B. Indeed, if the configuration had been as illustrated in FIG. 2B (in which the lateral edge of the bottom layer is underneath the top layer), two patterns with a different shape (different width/amplitude) would have been obtained, as illustrated in FIGS. 4A and 4B.

Attention is now drawn to FIG. 5D. In the method of FIG. 5A, the width difference of the two patterns has been used to determine to which layer (top layer, bottom layer) each lateral edge belongs. The method of FIG. 5D uses a relationship between an amplitude of the patterns in the derivative signal and the depth in the specimen to differentiate between the peaks informative of edges of different layers. Indeed, in at least some cases, it is expected that the amplitude of the peak of the derivative signal corresponding to the lateral edge of the second layer (which is the bottom layer, and is therefore located deeper in the specimen) will be larger than the amplitude of the peak of the derivative signal corresponding to the lateral edge of the first layer (which is the top layer, and is located closer to the surface of the specimen than the second layer). In other words, the difference in the amplitude between the peaks can be used to indicate whether the peak corresponds to the lateral edge of the upper layer (small amplitude relative to the other peak) or to the lateral edge of the bottom layer (high amplitude relative to the other peak). In the example of FIG. 4B, since the second peak 470 has a smaller amplitude than the amplitude of the first peak 460, this indicates that the second peak 470 corresponds to the lateral edge of the bottom layer and that the first peak 460 corresponds of the lateral edge of the top layer. The position of the second peak in the derivative signal corresponds to the position of the lateral edge of the bottom layer and the position of the first peak in the derivative signal corresponds to the position of the lateral edge of the top layer. The position of each lateral edge of each layer can be used to determine the width of each layer.

Attention is now drawn to FIG. 5E. In some examples, it is possible to determine the amplitude of each pattern (peak), and to determine whether it matches an expected amplitude. For example, during simulations, it is possible to determine the expected amplitude (first expected amplitude) of the first peak and the expected amplitude (second expected amplitude) of the second peak. The method of FIG. 5E includes (operation 540) obtaining the first expected amplitude and/or the second expected amplitude, and further includes checking whether the derivative signal includes a peak with the first expected amplitude and/or another peak with the second expected amplitude. This enables identifying (operation 550) the first peak informative of the lateral edge of the first layer (top layer) and the second peak informative of the lateral edge of the second layer (bottom layer). The position of the lateral edge of each layer can therefore be identified, and, in turn, the width of each layer.

In some examples, it is possible to determine the width of each pattern (peak), and to determine whether it matches an expected width. For example, during simulations, it is possible to determine the expected width (first expected width) of the first peak and the expected width (second expected width) of the second peak, and then to check in the derivative signal whether peaks with the first and second expected widths are present.

Note that the various principles described above are applicable to more than two layers. Assume for instance that N vertically stacked layers L₁ to L_{N} (with N equal to or greater than two), each of a different width, are present in the specimen. As a consequence, the lateral edge of each layer is located at a different location. Assume that each layer is located at a different depth in the specimen: each layer Lᵢ₊₁ is located at a higher depth than layer Lᵢ, with I from 1 to N−1, and each layer Lᵢ₊₁ has a smaller width than layer Lᵢ, with i from 1 to N−1. Assume that the landing energy of the acquisition signal of the specimen has been selected such that the acquisition signal, or the derivative signal of the acquisition signal, includes N pattern (peaks) P₁ to P_{N} which differ by their shape (each peak Pᵢ is informative of the lateral edge of layer Lᵢ, with i from 1 to N). In particular, it is expected that the width of each peak P₁₊₁ will be larger than the width of each peak Pᵢ, in the derivative signal, with i from 1 to N−1. It is therefore possible to identify the lateral edge of each layer L₁ to L_{N}, by identifying the peaks in the derivative signal, and their respective width. The larger the width of a peak of the derivative signal, the deeper the layer to which the lateral edge belongs. Note that the identification can be performed in the acquisition signal itself: it is expected that the slope of each pattern Pᵢ₊₁ (informative of a lateral edge) will be smaller than the slope of each pattern Pᵢ, in the derivative signal, with i from 1 to N−1.

In some examples, it is possible to identify the lateral edge of each layer L₁ to L_{N}, by identifying the peaks in the derivative signal, and their respective amplitude. Indeed, in some cases, the larger the amplitude of a peak of the derivative signal, the smaller the depth of the layer to which the lateral edge belongs. Conversely, the smaller the amplitude of a peak of the derivative signal, the higher the depth of the layer to which the lateral edge belongs.

In some examples, assume that the expected amplitude of each peak has been determined using simulation(s). It is then possible to check whether the derivative signal includes N peaks, each one with the expected amplitude. If there is a correspondence, it is possible to order the position of the lateral edges, depending on the height of the layers.

Generation of different patterns in the acquisition signal, or in the derivative signal of the acquisition signal, informative of the different lateral edges of the different layers located at different depths, results from a selection of an appropriate landing energy, which, in turn, enables generating a beam which widens progressively with the depth.

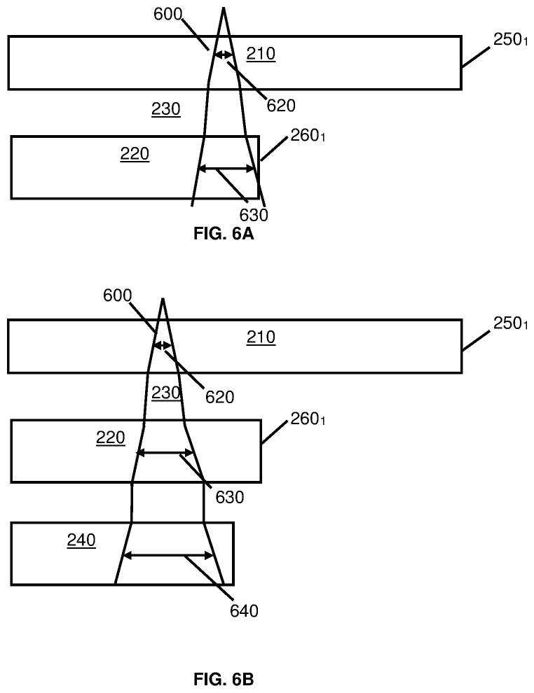

A non-limitative example of an electron beam 600 used at operation 300 is illustrated in FIG. 6A. The width of the electron beam 600 progressively increases when the electron beam 600 further penetrates the specimen. In particular, the electron beam 600 has a first (average) width value 620 at a height of the first layer 210 and a second (average) width value 630 at a height of the second layer 220. The first average width value 620 is smaller than the second average width value 630. This means that the resolution of the beam at the edge of the top layer is higher than the resolution of the beam at the edge of the bottom layer.

More generally, the specimen can include N vertically stacked layers L₁ to L_{N}, with N≥2, wherein each layer Lᵢ₊₁ is located deeper in the specimen than layer Lᵢ. The electron beam can be selected to have a width which expands from a height of a layer Lᵢ to a height of the next layer Lᵢ₊₁, with i from 1 to N−1. FIG. 6B illustrates this configuration with three layers, for which the electron beam 600 has a first (average) width value 620 at a height of the first layer 210, a second (average) width value 630 at a height of the second layer 620 and a third (average) width value 640 at a height of the third layer 640. The first average width value 620 is smaller than the second average width value 630 and the second average width value 630 is smaller than the third average width value 640. This means that the resolution of the beam at the edge of the top layer is higher than the resolution of the beam at the edge of the middle layer, and is higher than the resolution of the beam at the bottom layer. This enables differentiating between the lateral edges of the different layers buried at a different depth in the specimen.

Note that the width of the pattern informative of a lateral edge in the derivative signal increases with the depth of the layer to which the lateral edge belongs (in a scenario as depicted in FIGS. 6A and 6B, in which the edge of each layer is underneath another layer). Conversely, the width of the pattern informative of a lateral edge decreases with the landing energy. Indeed, the higher the landing energy, the better the resolution, and therefore the smaller the width of the pattern for each lateral edge.

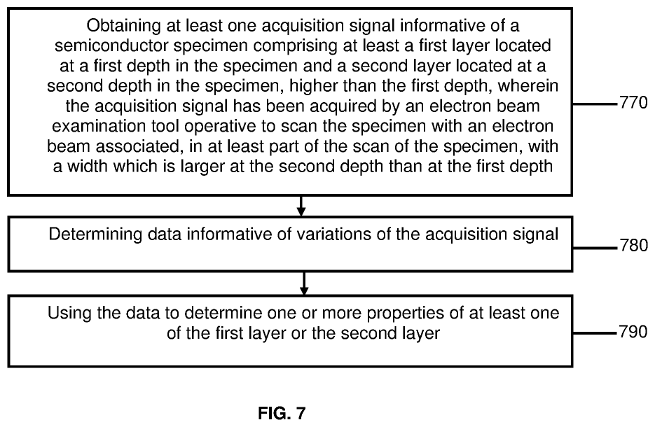

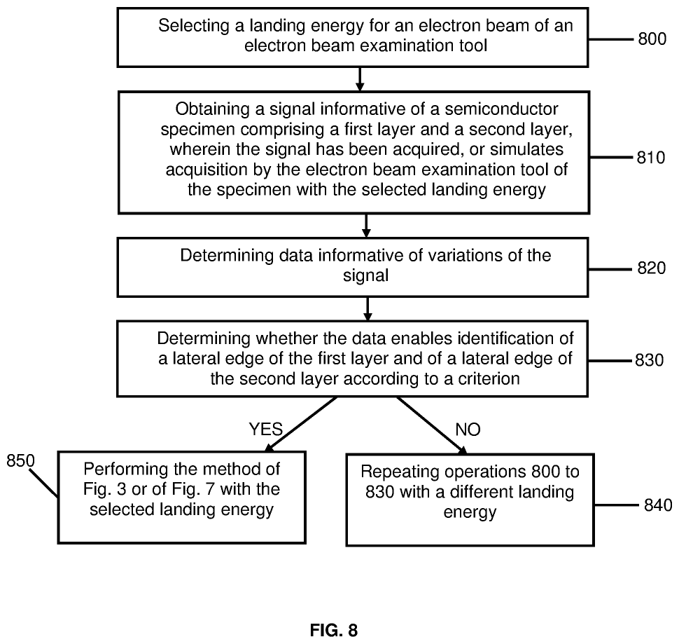

Attention is now drawn to FIG. 7 which illustrates a method relying on similar principles as the method of FIG. 3.

Assume that the specimen includes at least a first top layer (located a first depth) and a second bottom layer (located a second depth), with different widths (see e.g., FIG. 2A).

The method of FIG. 7 includes obtaining (operation 770) at least one acquisition signal informative of the specimen comprising at least a first layer located at a first depth in the specimen, and a second layer located at a second depth in the specimen, higher than the first depth. Note that the specimen can include more than two layers, which are vertically stacked, and are associated with different widths. The acquisition signal has been acquired by an electron beam examination tool operative to scan the specimen with an electron beam associated, in at least part of the scan of the specimen, with a width which is larger at the second depth than at the first depth. Non-limitative examples of this electron beam have been provided in FIGS. 6A and 6B.

For example, the average width value of the beam at the depth of the first layer is smaller than the average width value of the beam at the depth of the second layer.

In other examples, the maximal width value of the beam at the depth of the first layer is smaller than the minimal width value of the beam at the depth of the second layer. In other examples, the maximal width value of the beam at the depth of the first layer is smaller than the maximal width value of the beam at the depth of the second layer.

The method further includes using the acquisition signal, or a signal derived from the acquisition signal (e.g., derivative signal), to determine one or more properties of at least one of the first layer or the second layer (or of additional layers, if they are present). As explained above, this can include identifying different patterns in the acquisition signal, or in a signal derived from the acquisition signal, each pattern being informative of a different edge. In the example of FIG. 7, the method is described in a case in which the derivative signal is used to determine the patterns—however, the same method can be used to determine patterns (steep slopes) in the acquisition signal itself.

The method of FIG. 7 further includes (operation 780) determining data informative of variations of the acquisition signal. In particular, operation 780 can include determining a signal which is the derivative of the acquisition signal. In some examples, data informative of variations of the acquisition signal can include data informative of the width of each peak. Note that this is not limitative and data informative of variations of the acquisition signal can include the amplitude of each peak, or the area of each peak, or other relevant data characterizing each peak.

The method further includes (operation 790) using the data to determine one or more properties of at least one of the first layer or the second layer (or of additional layers, if they are present). Operation 790 can include determining the position of each lateral edge of each layer, based on the difference in width or amplitude of the peak informative of each lateral edge, as explained above. The position of each edge along the horizontal X axis and the vertical Z axis can be determined.

As explained above, the width of a peak of a lateral edge increases with the depth. It is therefore possible to differentiate between the peak of the bottom layer (large width) and the peak of the top layer (small width). This is applicable to N layers which generate N different peaks with N different widths. Alternatively, or in addition, it is possible to determine the amplitude of each peak. In at least some examples, the amplitude of a peak decreases with the depth. It is therefore possible to differentiate between the peak of the bottom layer (small amplitude) and the peak of the top layer (high amplitude).

Generation of the electron beam (with a width which progressively increases from the first layer to the second layer—or more generally, from each layer to the next layer located beneath) can be performed by selecting a landing energy which is within an appropriate range. If the landing energy is too high, then the electron beam tends to have a constant width. If the landing energy is too small, then the signal informative of the second layer (which is deeper than the first layer) has a signal to noise ratio which is too small to enable further processing. Therefore, the landing energy can be selected in an intermediate range. The intermediate range can vary from one tool to another and can depend on the number of layers and their properties (dimensions, composition, etc.). The intermediate range can be determined using simulations and/or experimental results. As explained above, the acquisition signal can be processed to provide, for each lateral edge of each layer, a derivative signal in which a peak is associated with each lateral edge. It is therefore possible to perform iterations in the range of the landing energy of the electron beam, until a derivative signal with two distinct peaks with a different standard deviation (or more generally N distinct peaks depending on the number of stacked layers) is obtained.

A non-limitative method of generating the electron beam with the appropriate shape is illustrated in FIG. 8. The method of FIG. 8 includes (operation 800) selecting a landing energy for the electron beam. The method further includes (operation 810) obtaining a signal informative of a semiconductor specimen comprising a first layer and a second layer. The first layer can be separated from the second layer by another layer which has a density which is smaller than the first layer and the second layer. As mentioned above, the specimen can include more than two layers. In some examples, the signal simulates acquisition by the electron beam examination tool of the specimen with the selected landing energy. This simulation can be performed using Monte-Carlo simulations. In other examples, the signal can be a signal acquired by an electron beam acquisition tool with the selected landing energy. The method further includes (operation 820) determining data informative of variations of the signal. In particular, operation 820 can include determining a derivative signal which corresponds to the derivative of the signal, and determining data informative of a width (such as, but not limited to, standard deviation) of peaks of the derivative signal. The method further includes (operation 830) determining whether the data enables identification of a lateral edge of the first layer and of a lateral edge of the second layer according to a criterion. The criterion can dictate that the (simulated or real) derivative signal includes patterns (peaks) which correspond to the location of the lateral edges of the two layers. The criterion can dictate that the peaks corresponding to the lateral edges of the layers are sufficiently visible in the simulated derivative signal. The criterion can dictate that the peaks corresponding to the lateral edges of different layers located at a different depth differ sufficiently in their position along the horizontal axis, and differ sufficiently in their shape (e.g., in their width and/or in their amplitude), such that it is possible to differentiate between them.

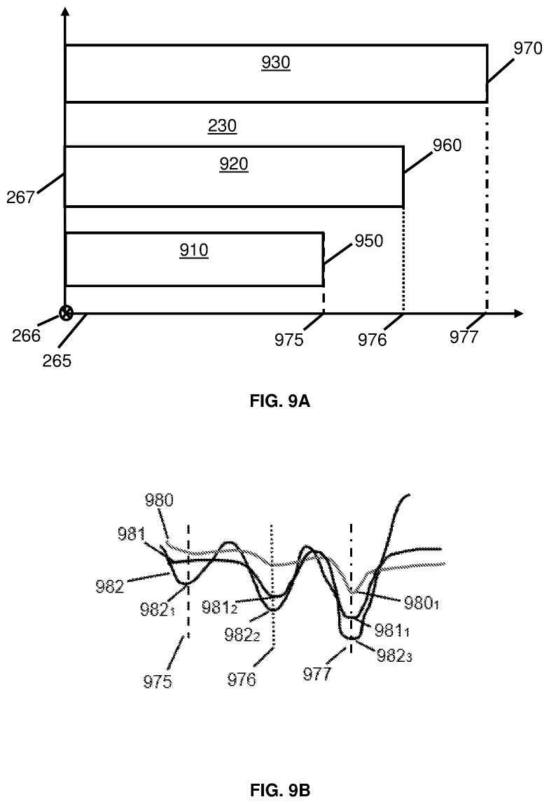

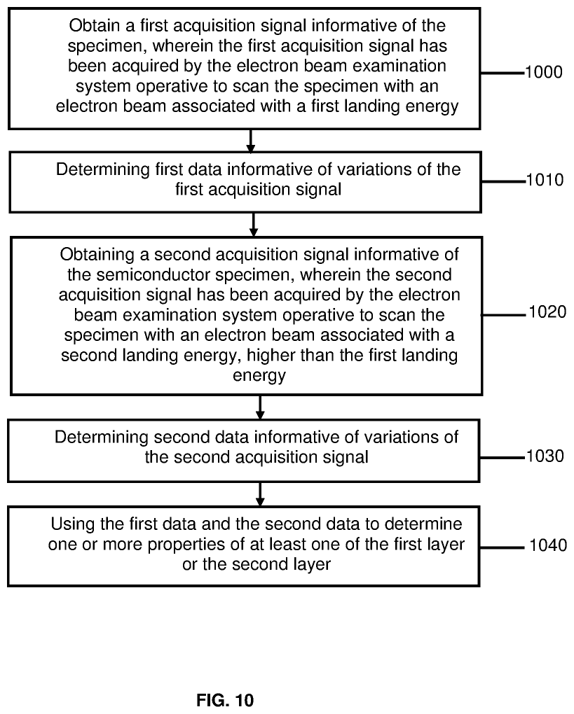

Operation 830 can include determining whether, for each lateral edge, a peak is present in the derivative signal at the location of the lateral edge (or a steep slope is present in the acquisition signal, which is equivalent). It is possible to verify whether the derivative signal includes a corresponding peak (local minimum in this example) for each lateral edge, using simulated signals and/or real acquisition signals. A non-limitative example is illustrated in FIGS. 9A and 9B. Assume that a specimen includes three layers: a first layer 910 with a lateral edge 950 located at position (along the horizontal X axis) 975, a second layer 920 with a lateral edge 960 located at position (along the horizontal X axis) 976, and a third layer 930 with a lateral edge 970 located at position (along the horizontal X axis) 977. Derivative signals are illustrated in FIG. 9B for different landing energies. For a first landing energy (e.g., equal to 6 keV), a first derivative signal 980 is obtained, for a second landing energy (e.g., equal to 12 keV), a second derivative signal 981 is obtained, and for a third landing energy (e.g., equal to 30 keV), a third derivative signal 982 is obtained. In the third derivative signal 982, three peaks 982₁, 982₂ and 982₃ are present, at a position which corresponds to the three edges. In the second derivative signal, only two peaks 981₁ and 981₂ are present. In the first derivative signal 980, only one peak 980₁ is present. As a consequence, at least the landing energy corresponding to the third derivative signal 982 should be selected for acquiring an acquisition signal from the specimen. If the landing energy is further increased over 30 keV (the corresponding simulation is not depicted in FIG. 9B), the standard deviation of each peak becomes similar for each of the three peaks, thereby preventing the ability to differentiate between the peaks based on their width. Note that it is possible to acquire different acquisition signals of the specimen (in addition to the selected landing energy), with different landing energies, in order to differentiate between the lateral edges. This will be discussed hereinafter with reference to FIG. 10.

Note that it can occur that two landing energies provide two derivative signals with the same number of peaks (corresponding to the lateral edges), but one signal is such that there is a better differentiation between the peaks than the other. In particular, the difference in width between the peaks is larger in one signal than in the other. In this case, the landing energy corresponding to the signal with the best differentiation between the peaks can be used. This is however not limitative.

As shown in FIG. 8, if the landing energy is such that data informative of variations of the signal meets the criterion, this indicates that the landing energy can be selected for acquiring an acquisition signal from the specimen. In particular, this indicates that the electron beam with the selected landing energy is associated with a width which expands (sufficiently) from the depth of the first layer to the depth of the second layer, such as a signal informative of variations of the acquisition signal will include a first peak informative of a lateral edge of the first layer, and a second peak informative of a lateral edge of the second layer, wherein data informative of a width of the second peak is larger than data informative of a width of the first peak. Therefore, the methods of FIG. 3 and/or FIG. 7 can be performed with at least an electron beam associated with the selected landing energy (as indicated in operation 850 in FIG. 8). It is also possible to acquire additional acquisitions signals for different landing energies, in order to further differentiate between the lateral edges of the different layers.

If the landing energy is such that data informative of variations of the signal does not meet the criterion, operations 800 to 830 can be repeated with a different landing energy (which is typically higher than the landing energy used at the previous iteration), as indicated in operation 840 in FIG. 8. Once a landing energy enabling generating the electron beam with the desired shape (which in turn, provides differentiable patterns of different shapes in the derivative signal for the different lateral edges of the different buried layers) has been obtained, the method can be stopped, and the selected landing energy can be output for further usage in real acquisition. In particular, the selected landing energy can be used to acquire an acquisition signal in the methods of FIG. 3 and/or FIG. 7.

Attention is now drawn to FIG. 10.

The method of FIG. 10 includes obtaining (operation 1000) a first acquisition signal informative of a semiconductor specimen. Assume for the sake of the example that the specimen comprises a first layer and a second layer, located at different depths in the specimen, and having a different width. Note that the method of FIG. 10 is applicable to a specimen including more than two layers. The first acquisition signal has been acquired by an electron beam examination system operative to scan the specimen with an electron beam associated with a first landing energy. The method of FIG. 10 further includes determining (operation 1010) first data informative of variations of the first acquisition signal.

The method of FIG. 10 further includes (operation 1020) obtaining a second acquisition signal informative of the semiconductor specimen, wherein the second acquisition signal has been acquired by the electron beam examination system operative to scan the specimen with an electron beam associated with a second landing energy, higher than the first landing energy.

The method of FIG. 10 further includes (operation 1030) determining second data informative of variations of the second acquisition signal.

The method of FIG. 10 further includes (operation 1040) using the first data and the second data to determine one or more properties of at least one of the first layer or the second layer. This can include determining at least one of a position of an edge of the first layer or a position of an edge of the second layer.

Operation 1040 can include comparing the first data with the second data. In particular, assume that the first data corresponds to the derivative signal of the first acquisition signal and that the second data corresponds to the derivative signal of the second acquisition signal. Assume that the derivative signal of the second acquisition signal includes two peaks PK₁ and PK₂ at two different locations X₁ and X₂, and that the derivative signal of the first acquisition signal includes a single peak PK′₁ at the same location X₁ than the peak P₁ of the second data. This indicates that the location X₁ corresponds to the lateral edge of a top layer (since a peak is present at this location in both derivative signals), and that the location X₂ corresponds to the lateral edge of a bottom layer (since a peak is present at this location only in the derivative signal acquired with a higher energy).

The method of FIG. 10 can be illustrated with the derivative signals depicted in FIG. 9B. The first derivative signal 980 includes a single peak 980₁, which is present at location 977. The second derivative signal 981 includes two peaks: a first peak 981₁ at location 977 and a second peak 981₂ at location 976. This indicates that location 977 corresponds to an edge of an upper layer, whereas location 976 corresponds to an edge of a layer which is located deeper in the specimen. The third derivative signal 982 includes three peaks: a first peak 982₁ at location 975, a second peak 982₂ at location 976 and a third peak 982₃ at location 977. This indicates that location 977 corresponds to the edge of a layer which is located deeper in the specimen than the layer which has a local edge located at location 976. The method has therefore enabled identifying three layers, a first top layer with an edge located at location 975, a second middle layer with an edge located at location 976, and a third bottom layer with an edge located at location 977.

This method, which uses different acquisition signals at different landing energies, can be used to identify lateral edges of more than two layers. Assume that the specimen includes N vertically stacked layers L₁ to L_{N}, with N≥2, wherein each layer has a different width. The method can include obtaining a plurality of different acquisition signals acquired at different landing energies, and determining, for each given acquisition signal, data informative of variations of the given acquisition signal (e.g., the derivative of the given acquisition signal). This enables obtaining a set of data. The method can further include using the set of data to determine one or more properties of one or more of the layers L₁ to L_{N}, such as the position of the lateral edge of each layer. Assume that N acquisition signals have been acquired, with landing energies E₁ to E_{N}(with Eᵢ<Eᵢ₊₁, for i from 1 to N−1). It is possible to compare the derivative signal of the acquisition signal acquired at landing energy Eᵢ₊₁ with the derivative signal of the acquisition signal acquired at landing energy Eᵢ. If a first peak appears both at energy Eᵢ and at energy Eᵢ₊₁, and a second peak appears only at energy Eᵢ₊₁, this indicates that the first peak corresponds to a lateral edge of layer which is above the layer associated with the lateral edge corresponding to the second peak. It is therefore possible to acquire progressively different acquisition signals, each time with a higher landing energy, in order to differentiate between the lateral edges of the different layers. Note that in at least some implementations of this method, it is not necessary to compare the widths (or amplitudes) of the various peaks (as explained e.g., in the methods of FIGS. 5A and 5B) and it is sufficient to compare the number of peaks between the derivative signals of the acquisition signals acquired at different energies, in order to identify the peak corresponding to the lateral edge of each layer. In some implementations of this method, it is possible to both compare the number of peaks between at least some of the derivative signals (as explained with FIG. 10) and to compare the width (or amplitude) of the peaks in a given derivative signal (as explained in the methods of FIGS. 3, 5A, 5D and 7), in order to differentiate between the lateral edges of the various layers located at different depths.

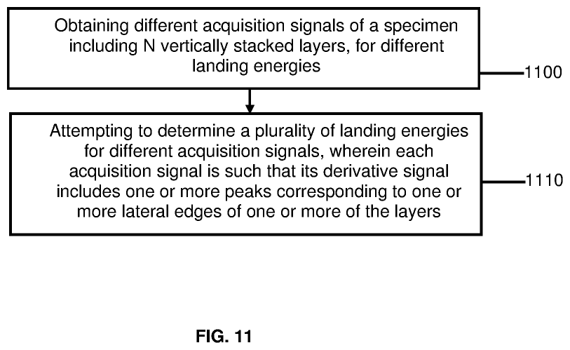

Attention is now drawn to FIG. 11, which depicts a method which can be used to generate the acquisition signals used e.g., in the method of FIG. 10. The method of FIG. 11 can rely on the usage of simulated acquisition signals and/or real acquisition signals.

Assume that the specimen includes N vertically stacked layers L₁ to L_{N}, with N≥2, wherein each layer has a different width. In order to simplify the notation, assume that each layer L_{I} has a smaller width that the next layer L_{I+1} (this is however not limitative). The method of FIG. 11 can include obtaining (using simulations and/or real acquisitions) different acquisition signals for different landing energies (operation 1100).

In some examples, it is attempted to find a plurality of landing energies corresponding to different acquisition signals. Each acquisition signal is such that its derivative signal includes one or more patterns (peaks) corresponding to one or more lateral edges of the layers L₁ to L_{N}.

In some examples, it is attempted to find at least N landing energies E₁ to E_{N}(with E_{I}<E_{I+1}) corresponding to N different acquisition signals AS₁ to AS_{N}. Each acquisition signal AS_{I} is such that its derivative signal includes I patterns (peaks) corresponding to the lateral edges of layers L₁ to L_{I} (operation 1110), but does not include patterns (peaks) corresponding to lateral edges of other layers L_{I+1} to L_{N} (that is to say lateral edges of layers located below the layer L₁—for I equal to N there is no layer below layer L_{N}). For example, the first derivative signal of AS₁ includes one peak informative of the lateral edge of layer L₁ (but does not include additional peaks informative of the other lateral edges of the other layers), the second derivative signal of AS₂ includes two peaks informative of the lateral edges of layers L₁ and L₂ (but does not include additional peaks informative of the other lateral edges of the other layers), etc. Note that this is not limitative, and it is possible to acquire less than N acquisition signals or more than N acquisition signals.

Once the plurality of landing energies has been obtained, it is possible to acquire a plurality of acquisition signals with this plurality of landing energies, and to identify the position of the lateral edges of the N layers, similarly to the method described with reference to FIG. 10. Note that FIG. 10 describes the case of different acquisitions performed at two landing energies, but this can be generalized to different acquisitions at different landing energies for identifying the lateral edges of N layers. A comparison of the pattern distribution (peak distribution) between the derivative of each acquisition signal AS_{I} acquired at energy E_{I} with the derivative of the acquisition signal AS_{I+1} acquired at energy E_{I+1} enables identifying the lateral edge of layer L_{I+1}. Indeed, the peak which appears at energy E_{I+1} but does not appear at energy E_{I} should correspond to the lateral edge of layer L_{I+1}. The method can be performed iteratively for all layers until all lateral edges have been identified.

In some examples, it is not possible to find (during simulations and/or using real experiments) a landing energy which enables obtaining exactly I peaks for layer L_{I} which correspond to the I lateral edges, for at least one value of I (between 1 and N). Assume for example that for layer L₁, it is not possible to find a landing energy for which a single peak corresponding to the lateral edge of the layer L₁ is present in the derivative of the acquisition signal, but only two peaks, corresponding to the lateral edges of layer L₁ and L₂. In this case, it is possible to rely on the principles described with reference to FIGS. 3, 5A, 5D, 5E and 7. In particular, it is possible to determine data informative of the width of each peak (or of the amplitude), and to determine, based on this data, which peak corresponds to a lateral edge of a top layer, and which peak corresponds to a lateral edge of a bottom layer, as explained with reference to FIGS. 5A and 5D. In the example above, the peak with the highest width corresponds to the lateral edge of layer L₂, whereas the peak with the smallest width corresponds to the lateral edge of layer L₁.

In the present description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, it is appreciated that throughout the specification discussions utilizing terms such as “obtaining”, “using”, “determining”, “differentiating”, “identifying”, “selecting”, or the like, refer to the action(s) and/or process(es) of at least one processing circuitry that manipulate and/or transform data into other data, said data represented as physical, such as electronic, quantities and/or said data representing the physical objects.

The term “specimen” used in this specification should be expansively construed to cover any kind of wafer, masks, and other structures, combinations and/or parts thereof used for manufacturing semiconductor integrated circuits, magnetic heads, flat panel displays, and other semiconductor-fabricated articles.

The term “examination” used in this specification should be expansively construed to cover any kind of metrology-related operations, as well as operations related to detection and/or classification of defects in a specimen during its fabrication. Examination is provided by using non-destructive examination tools during or after manufacture of the specimen to be examined. By way of non-limiting example, the examination process can include runtime scanning (in a single or in multiple scans), sampling, reviewing, measuring, classifying and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes, atomic force microscopes, optical inspection tools, etc.

The processing circuitry 104 can comprise, for example, one or more processors operatively connected to one or more computer memories loaded with executable instructions for executing operations, as further described below. The processing circuitry encompasses a single processor or multiple processors, which may be located in the same geographical zone, or may, at least partially, be located in different zones, and may be able to communicate together.

The one or more processors referred to herein can represent one or more general-purpose processing devices such as a microprocessor, a central processing unit, or the like. More particularly, a given processor may be one of: a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

It is to be noted that while the present disclosure refers to the processing circuitry 104 being configured to perform various functionalities and/or operations, the functionalities/operations can be performed by the one or more processors of the processing circuitry 104 in various ways. By way of example, the operations described hereinafter can be performed by a specific processor, or by a combination of processors. The operations described hereinafter can thus be performed by respective processors (or processor combinations) in the processing circuitry 104, while, optionally, at least some of these operations may be performed by the same processor. The present disclosure should not be limited to be construed as one single processor always performing all the operations.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately, or in any suitable sub-combination. In the following detailed description, numerous specific details are set forth in order to provide a thorough understanding of the methods and apparatus.

In embodiments of the presently disclosed subject matter, fewer, more, and/or different stages than those shown in the methods of FIGS. 3, 5A, 5D, 5E, 7, 8, 10 and 11 may be executed. In embodiments of the presently disclosed subject matter, one or more stages illustrated in the methods of FIGS. 3, 5A, 5D, 5E, 7, 8, 10 and 11 may be executed in a different order, and/or one or more groups of stages may be executed simultaneously.

It is to be understood that the invention is not limited in its application to the details set forth in the description contained herein or illustrated in the drawings.

It will also be understood that the system according to the invention may be, at least partly, implemented on a suitably programmed computer. Likewise, the invention contemplates a computer program being readable by a computer for executing the method of the invention. The invention further contemplates a non-transitory computer-readable memory tangibly embodying a program of instructions executable by the computer for executing the method of the invention.

The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

What is claimed is:

1. A system comprising one or more processing circuitries configured to:
obtain an acquisition signal informative of a semiconductor specimen comprising at least a first layer located at a first depth in the specimen, and a second layer located at a second depth in the specimen, higher than the first depth,
wherein the acquisition signal has been acquired by an electron beam examination system operative to scan the specimen with an electron beam associated with a landing energy enabling generating, in at least one of the acquisition signal or in a signal derived from the acquisition signal, a first pattern informative of a lateral edge of the first layer, and a second pattern informative of a lateral edge of the second layer, wherein the second pattern differs from the first pattern, and
use at least one of the acquisition signal or the signal derived from the acquisition signal, to determine one or more properties of at least one of the first layer or the second layer.

2. The system of claim 1, wherein the one or more properties include at least one of:
a position of the lateral edge of the first layer,
a position of the lateral edge of the second layer,
a width of the first layer, or
a width of the second layer.

3. The system of claim 1, wherein (i) or (ii) is met:
(i) the first pattern corresponds to a first peak informative of the lateral edge of the first layer, and the second pattern corresponds to a second peak informative of the lateral edge of the second layer, wherein the first peak and the second peak are differentiable by their width;
(ii) the first pattern corresponds to a first slope informative of the lateral edge of the first layer, and the second pattern corresponds to a second slope informative of the lateral edge of the second layer, wherein the first slope differs from the second slope.

4. The system of claim 1, configured to use a relationship between data informative of a shape of the first pattern and of the second pattern and a depth within the specimen, to differentiate between the first pattern informative of the lateral edge of the first layer located at the first depth in the specimen and the second pattern informative of the second layer located at the second depth in the specimen, higher than the first depth.

5. The system of claim 1, configured to use at least one of:
(i) a difference between data informative of a width of the first pattern and data informative of a width of the second pattern to identify the first pattern informative of the lateral edge of the first layer and the second pattern informative of the lateral edge of the second layer,
(ii) a difference between data informative of an amplitude of the first pattern and data informative of an amplitude of the second pattern to identify the first pattern informative of the lateral edge of the first layer and the second pattern informative of the lateral edge of the second layer, or
(iii) a difference between data informative of a slope of the first pattern and data informative of a slope of the second pattern to identify the first pattern informative of the lateral edge of the first layer and the second pattern informative of the lateral edge of the second layer.

6. The system of claim 1, wherein the second layer is located deeper in the specimen than the first layer, wherein the system is configured to identify that a pattern of the signal corresponds to the first pattern informative of the lateral edge of the first layer and that another pattern of the signal corresponds to the second pattern informative of the lateral edge of the second layer based on a determination that that data informative of a width of said another pattern is larger than data informative of a width of said pattern.

7. The system of claim 1, wherein the second layer is located deeper in the specimen than the first layer, wherein the system is configured to identify that a pattern of the signal corresponds to the first pattern informative of the lateral edge of the first layer, and that another pattern of the signal corresponds to the second pattern informative of the lateral edge of the second layer, based on a determination that that data informative of an amplitude of said another pattern is larger than data informative of an amplitude of said pattern.

8. The system of claim 1, wherein the second layer is separated by the first layer by a layer which has a density which is smaller than a density of the first layer and than a density of the second layer.

9. The system of claim 1, wherein the landing energy has been selected using one or more simulations.

10. The system of claim 9, wherein the one or more simulations include:
determining data informative of variations of a simulated acquisition signal of the specimen for different landing energies of the simulated acquisition signal, and
selecting a given landing energy for which a given simulated acquisition signal associated with this given landing energy, or a given signal derived from this given simulated acquisition signal, includes a first pattern informative of the lateral edge of the first layer and a second pattern informative of the lateral edge of the second layer, wherein the first pattern differs from the second pattern according to a criterion.

11. The system of claim 1, configured to:
obtain a first acquisition signal informative of the specimen, wherein the first acquisition signal has been acquired by the electron beam examination system operative to scan the specimen with an electron beam associated with a first landing energy,
determine first data informative of variations of the first acquisition signal,
obtain a second acquisition signal informative of the specimen, wherein the second acquisition signal has been acquired by the electron beam examination system operative to scan the specimen with an electron beam associated with a second landing energy, higher than the first landing energy,
determine second data informative of variations of the second acquisition signal, and
use the first data and the second data to determine at least one of a position of the lateral edge of the first layer or a position of the lateral edge of the second layer.

12. The system of claim 1, wherein the specimen includes N vertically stacked layers L₁ to L_{N}, with N≥2, wherein each layer has a different width, wherein the system is configured to:
obtain a plurality of different acquisition signals acquired at different landing energies,
determine, for each given acquisition signal data, a derivative signal informative of variations of the given acquisition signal, thereby obtaining a set of derivative signals,
use the set of derivative signals to determine one or more properties of one or more of the layers L₁ to L_{N}.

13. The system of claim 12, configured to:
compare a first derivative signal obtained at a first landing energy and a second derivative signal obtained at a second landing energy, higher than the first landing energy, and
determine a position of one or more lateral edges of one or more of the layers L₁ to L_{N} based on a comparison between one or more patterns that appear in the second derivative signal and one or more patterns that appear in the first derivative signal.

14. The system of claim 1, configured to perform at least one of (i) or (ii):
(i) obtaining a first expected amplitude for the first pattern and identifying the first pattern based on this first expected amplitude, or
(ii) obtaining a second expected amplitude for the second pattern and identifying the second pattern based on this second expected amplitude.

15. The system of claim 1, wherein the specimen includes N vertically stacked layers L₁ to L_{N}, with N≥2, wherein each layer has a different width, wherein the system is configured to:
obtain an acquisition signal informative of the specimen, wherein the acquisition signal has been acquired by an electron beam examination system operative to scan the specimen with an electron beam associated with a width which expands from a depth of a layer Lᵢ to a depth of the next layer Lᵢ₊₁, with i from 1 to N−1,
determine data informative of variations of the acquisition signal, and
use the data to determine one or more properties of at least one of the layers L₁ to L_{N}.

16. A system comprising one or more processing circuitries configured to:
obtain at least one acquisition signal informative of a semiconductor specimen comprising at least a first layer located at a first depth in the specimen, and a second layer located at a second depth in the specimen, higher than the first depth,
wherein the at least one acquisition signal has been acquired by an electron beam examination tool operative to scan the specimen with an electron beam associated, in at least part of the scan of the specimen, with a width which is larger at the second depth than at the first depth, and
use at least one of the acquisition signal, or a signal derived from the acquisition signal, to determine one or more properties of at least one of the first layer or the second layer.

17. The system of claim 16, wherein said electron beam enables generating, in the acquisition signal, or the signal derived from the acquisition signal, a first pattern informative of a lateral edge of the first layer, and a second pattern informative of a lateral edge of the second layer, wherein at least one of (i), (ii) or (iii) is met:
(i) data informative of a width of the second pattern is larger than data informative of a width of the first pattern,
(ii) data informative of an amplitude of the first pattern is larger than data informative of an amplitude of the second pattern, or
(iii) data informative of a slope of the first pattern differs from data informative of a slope of the second pattern.

18. The system of claim 16, configured to perform a determination of at least one of a position of the lateral edge of the first layer or a position of the lateral edge of the second layer, said determination comprising identifying at least one of the first pattern or the second pattern based on at least one of:
(i) data informative of a width of the first pattern and of the second pattern;
(ii) data informative of an amplitude of the first pattern and of the second pattern; or
(iii) data informative of a slope of the first pattern and data informative of a slope of the second pattern.

19. A non-transitory computer readable medium comprising instructions that, when executed by one or more processing circuitries, cause the one or more processing circuitries to perform:
obtaining a plurality of different acquisition signals of a semiconductor specimen including N vertically stacked layers L₁ to L_{N}, with N≥2, wherein each layer has a different width, acquired at different landing energies, and
using the plurality of different acquisition signals to determine one or more properties of one or more of the layers L₁ to L_{N}.

20. The non-transitory computer readable medium of claim 19, comprising instructions that, when executed by the one or more processing circuitries, cause the one or more processing circuitries to identify patterns in the different acquisition signals to determine edge position of each of the layers L₁ to L_{N}.
